(19) United States
(12) Patent Application Publication
(10) Pub. No.: US 2023/0373609 A1
(43) Pub. Date: Nov. 23, 2023

(54) RIDGE STRUCTURE, WING, DESIGN METHOD OF RIDGE STRUCTURE, AND DESIGN PROGRAM FOR THE SAME

(71) Applicants: MITSUBISHI HEAVY INDUSTRIES, LTD., Tokyo (JP); TOHOKU UNIVERSITY, Sendai-shi (JP); JAPAN AEROSPACE EXPLORATION AGENCY, Tokyo (JP)

(72) Inventors: Kenji TOGAMI, Tokyo (JP); Minoru YOSHIMOTO, Tokyo (JP); Makoto HIROTA, Miyagi (JP); Yuji HATTORI, Miyagi (JP); Yuki IDE, Tokyo (JP)

(21) Appl. No.: 18/200,128

(22) Filed: May 22, 2023

(30) Foreign Application Priority Data
May 23, 2022 (JP) 2022-083772

(51) Int. Cl. B64C 3/14; B64F 5/00

(52) U.S. Cl. CPC B64C 3/14; B64F 5/00; B64C 2003/148

(57) ABSTRACT

The ridge structure has ridge elements provided on a top face of a leading edge region directly downstream of a leading edge, which is a laminar flow region of a wing having a swept-back angle relative to a mainstream and provided with a leading edge, and extending in parallel toward downstream of the mainstream. When an angle of a ridgeline connecting vertexes of the ridge elements in an extending direction of the ridge elements relative to x direction is OR, an angle of a flow line of a boundary layer external edge of the mainstream relative to the x direction is θe, and an angle of a wavefront of stationary cross-flow instability, which is a mode in which a stationary disturbance amplifies inside a boundary layer of the surface and appears as a stationary vortex row, relative to the x direction is θcf, θR is between θe and θcf.

### CROSS-REFERENCE TO RELATED APPLICATIONS

This application is based on Japanese Patent Application No. 2022-083772 filed on May 23, 2022, the contents of which is hereby incorporated by reference in its entirety.

### TECHNICAL FIELD

The present disclosure relates to a ridge structure suitable to be provided in a leading edge region of an object, a wing, a design method of a ridge structure, and a design program for the same.

### BACKGROUND ART

When a flow collides with a columnar object, which is represented by a wing of an aircraft, diagonally with a swept-back angle, a “cross-flow” occurs inside a boundary layer because the direction of a pressure gradient and the direction of a mainstream on the object surface differ from each other. In such a boundary layer, cross-flow instability amplifies a disturbance, and the boundary layer transitions from a laminar flow state to a turbulent flow state. When the boundary layer is in a turbulent flow state, this will undesirably cause a significant increase in the frictional resistance applied on the object surface.

Non-Patent Literature 1 proposes a method of installing disc-like protrusions, which are micro-discrete roughness elements (hereafter, referred to as “DRE”), at equal intervals on the leading edge of a swept-back wing and exciting a stationary cross-flow instability with a wavenumber βR. In this Non-Patent Literature 1, a physical mechanism to suppress a boundary-layer transition (laminar-turbulent transition) has already been described.

However, since an increase of the height of protrusions will cause the backwash of the protrusions to become a turbulent flow due to separation, the limit height tends to be low, and an amplitude of excited stationary cross-flow instability also tends to be weak. Although an actual flight test was conducted, no turbulent flow suppression effect (laminarization effect) was observed.

Patent Literature 1 discloses sinusoidal roughness elements (hereafter, referred to as “SRE”) that avoid the drawback of the DRE described above. It is proposed that the sectional shape in the span direction be wave-shaped concave and convex and the orientation of a ridgeline be matched to a flow line direction θe on the boundary layer external edge. It is shown that, since the concave and convex shape is a smooth shape in a direction along the flow line, the flow is not disturbed even if the height of the shape is increased to be two to three times higher than the DRE. It was thus shown that a strong vortex row was excited behind the SRE, and a higher turbulent flow suppression effect than that of the DRE was obtained.

On the other hand, there are riblets as those similar to the DRE or SRE described above (for example, see Patent Literature 2). Riblets have a similarity to the DRE or SRE in terms of having the purpose of reducing a frictional resistance and having a concave and convex shape. However, riblets are to reduce the frictional resistance in a turbulent flow boundary layer on which a boundary-layer transition has already taken place and thus differ from devices such as the DRE or SRE to suppress a boundary-layer transition. Riblets are installed in an object surface region already having a turbulent flow and are not provided near the leading edge as with the DRE or SRE. Further, a riblet simply has a wave-shaped concave and convex pattern along a flow line, and no consideration is taken for a cross-flow inside the boundary layer. Further, without being limited to wave-shaped concave and convex patterns such as a riblet, various concave and convex shapes inspired by shark skin have been proposed as an element having a frictional resistance reduction effect, however, these shapes are to reduce a frictional resistance in the turbulent flow boundary layer in the same manner as a riblet.

### CITATION LIST

### Non Patent Literature

[NPL 1]
Saric and two others, “American Institute of Aeronautics and Astronautics Paper, No. 1998-0781” (U.S.), 1998, pp. 1-13

### PATENT LITERATURE

[PTL 1]
International Publication No. WO2020/203284

[PTL 2]
International Publication No. WO2009/000703

### SUMMARY OF INVENTION

### Technical Problem

The SRE disclosed in Patent Literature 1 is expected to be arranged locally at a position near the leading edge, and the ridgeline is also formed as a straight line at an angle matching a flow line direction at the position. Since a vortex row behind the SRE is gradually weakened and attenuated as it travels rearward, there is a problem that the region where a turbulent flow suppression effect works is also limited to a region behind the SRE.

To further improve the SRE, it may be considered to further expand the wave-shaped concave and convex pattern rearward along the flow line direction. Since the flow line is curved, this requires the ridgeline connecting peaks of convex parts to be curved, accordingly. However, this causes a problem that the concave and convex pattern and a vortex row pattern of stationary cross-flow instability are not synchronized with each other but interfere with each other, and the vortex row may be collapsed.

The present disclosure has been made in view of such circumstances and intends to provide a ridge structure, a wing, a design method of a ridge structure, and a design program for the same that can suppress amplification of a disturbance due to cross-flow instability on a surface of a leading edge region of an object and cause a position at which a boundary-layer transition occurs to recede to expand a region of a laminar flow boundary layer.

### Solution to Problem

The ridge structure, the wing, the design method of the ridge structure, and the design program for the same of the present disclosure are as follows.

The ridge structure according to one aspect of the present disclosure has a plurality of ridge elements provided on a surface of a leading edge region directly downstream of a leading edge and extending in parallel toward downstream of a mainstream, the leading edge region is a laminar flow region of an object having a swept-back angle relative to the mainstream and provided with the leading edge, and the plurality of ridge elements have vertexes provided at a constant interval λR in a z direction parallel to a leading edge attachment line on which stagnation points attached to the leading edge are aligned. When an angle of a ridgeline connecting the vertexes of the ridge elements in an extending direction of the ridge elements relative to an x direction perpendicular to the leading edge attachment line is defined as a ridgeline angle θR, an angle of a flow line of a boundary layer external edge of the mainstream relative to the x direction is defined as a boundary layer edge velocity yaw angle θe, and an angle of a wavefront of stationary cross-flow instability, which is a mode in which a stationary disturbance amplifies inside a boundary layer of the surface and appears as a stationary vortex row, relative to the x direction is defined as a cross-flow instability angle θcf, the ridgeline angle θR is set between the boundary layer edge velocity yaw angle θe and the cross-flow instability angle θcf.

The design method of a ridge structure according to one aspect of the present disclosure is a designing method of a ridge structure, the ridge structure has a plurality of ridge elements provided on a surface of a leading edge region directly downstream of a leading edge and extending in parallel toward downstream of a mainstream, the leading edge region is a laminar flow region of an object having a swept-back angle relative to the mainstream and provided with the leading edge, and the plurality of ridge elements have vertexes provided at a constant interval λR in a z direction parallel to a leading edge attachment line on which stagnation points attached to the leading edge are aligned. The design method includes: when an angle of a ridgeline connecting the vertexes of the ridge elements in an extending direction of the ridge elements relative to an x direction perpendicular to the leading edge attachment line is defined as a ridgeline angle θR, an angle of a flow line of a boundary layer external edge of the mainstream relative to the x direction is defined as a boundary layer edge velocity yaw angle θe, and an angle of a wavefront of stationary cross-flow instability, which is a mode in which a stationary disturbance amplifies inside a boundary layer of the surface and appears as a stationary vortex row, relative to the x direction is defined as a cross-flow instability angle θcf, setting the ridgeline angle θR between the boundary layer edge velocity yaw angle Ae and the cross-flow instability angle θcf.

The design program according to one aspect of the present disclosure causes a computer to perform the design method described above.

### Advantageous Effects of Invention

With the ridge structure, it is possible to suppress amplification of a disturbance due to cross-flow instability on a surface of a leading edge region of an object and cause a position at which a boundary-layer transition occurs to recede to expand a region of a laminar flow boundary layer. This makes it possible to reduce a frictional resistance received by an object.

### BRIEF DESCRIPTION OF DRAWINGS

FIG. 1 is a perspective view illustrating a portion of a wing having a ridge structure according to one embodiment of the present disclosure.

FIG. 2 illustrates the ridge structure of FIG. 1 in which the upper diagram is a graph illustrating the ridge structure by contour lines and the lower diagram is a graph illustrating the height of ridge elements.

FIG. 3 is a graph illustrating a typical flow velocity distribution at a certain position on an object surface.

FIG. 4 is a graph illustrating the N-factor of stationary cross-flow instability obtained by linear stability analysis.

FIG. 5 is a function block diagram illustrating a computer that implements a design method of a ridge structure according to one embodiment of the present disclosure.

FIG. 6 is a graph illustrating an external edge velocity distribution used in Examples.

FIG. 7 is a graph illustrating a target mode before suppressing a boundary-layer transition.

FIG. 8 represents diagrams illustrating an example of the shape of SRE.

FIG. 9 is a graph illustrating a view of a boundary-layer transition when the SRE is installed.

FIG. 10 is a graph illustrating a boundary layer edge velocity yaw angle θe (s=1.00), a cross-flow instability angle θcf (s=0.834), and a ridgeline angle θR (s=0.917) at each chord position x.

FIG. 11 is a graph illustrating a numerical simulation result at s=0.834.

FIG. 12 is a graph illustrating a numerical simulation result at s=1.

FIG. 13 is a graph illustrating a numerical simulation result at s=0.917.

### DESCRIPTION OF EMBODIMENTS

One embodiment according to the present disclosure will be described below with reference to the drawings.

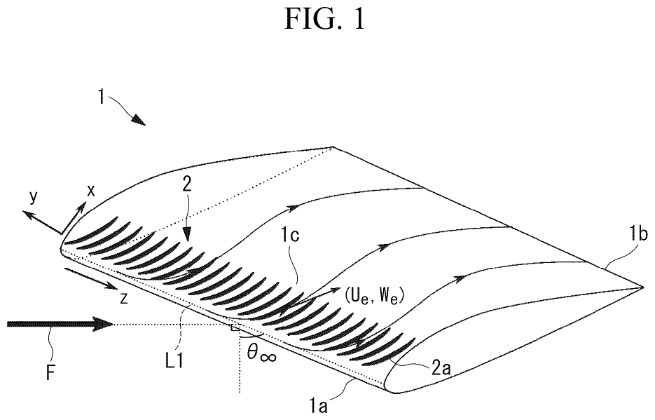

FIG. 1 illustrates a wing 1 (object) having a ridge structure 2. The wing 1 is used for an aircraft, for example, and is a swept-back wing having a swept-back angle θ∞ relative to a mainstream flow F. Note that FIG. 1 illustrates only a part in the span direction (z direction) in the wing 1. Thus, the ridge structure 2 is provided across substantially the overall length or across a desired predetermined region in the span direction of the wing 1.

Note that, although a wing shape is used for illustration as an example of an object in the present embodiment, the shape of an object is not limited to the wing shape in the present disclosure, and is widely applicable to flows around a columnar object such as a cylinder or the like.

The wing 1 has a suitable wing shape whose wing thickness increases from a leading edge 1a toward a tailing edge 1b and gradually decreases after reaching the maximum. However, the specific wing shape is not particularly limited.

In FIG. 1, the flow F represents a mainstream airflow received by the wing 1 when an aircraft with the wing 1 attached thereto travels straight ahead. During flight of the aircraft, stagnation points are attached to the leading edge 1a of the wing 1. These stagnation points are arranged into a line in a direction in which the leading edge 1a extends, and a leading edge attachment line L1 is formed.

The ridge structure 2 is formed on a top face 1c of the wing 1, more specifically, in the leading edge region directly downstream of the leading edge attachment line L1. The ridge structure 2 reduces a frictional resistance caused by viscosity of the flow F flowing on the wing 1. Note that the ridge structure 2 may be provided in the leading edge region of the backside of the wing 1. In the following description, however, the ridge structure 2 provided on the top face 1c of the wing 1 will be described.

As illustrated in FIG. 1, the position near the object surface in the leading edge region of the wing 1 where a boundary layer is formed is expressed by the following coordinate system.
x: the chord direction (coordinate in a direction perpendicular to the leading edge attachment line L1 and along the top face 1c of the wing 1)
y: the wall normal direction (y=0 corresponds to the top face 1c of the wing 1)
z: the span direction (direction parallel to the leading edge attachment line L1)

The position of the leading edge attachment line L1 is defined as x=y=0, and x (>0) denotes the distance from the leading edge attachment line L1 measured along the top face 1c of the wing 1.

The direction of the mainstream flow F is not parallel to the chord direction (not perpendicular to the leading edge attachment line L1) and forms the swept-back angle con.

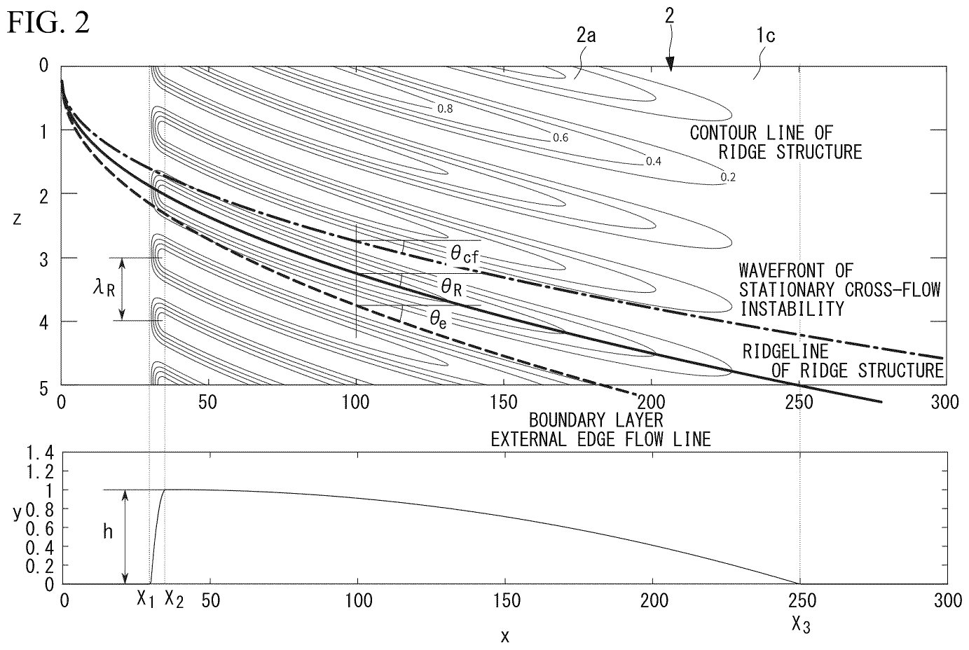

FIG. 2 illustrates the concave and convex pattern of the ridge structure 2 by contour lines. The ridge structure 2 has a plurality of ridge elements 2a and has the following characteristics.
The ridge elements 2a having the same shape are periodically aligned at an interval λR in the span direction. That is, concave and convex shapes of the wavenumber of βR=2π/λR are repeated into a wave shape along the span direction.
Each of the ridge elements 2a has a single vertex in a transverse cross section that is the sectional shape in the span direction. That is, the transverse sectional shape where these ridge elements 2a are periodically aligned may have, for example, a sine wave, a triangle wave, or the like.
When viewed in the chord direction, the ridge structure 2 is distributed in the leading edge region within the section from a front end position x1 close to the leading edge 1a to a rear end position x3. The peak height of the transverse sectional shape of each ridge element 2a gradually increases from the front end position x1 to a vertex position x2 and gradually decreases from the vertex position x2 to the rear end position x3. That is, the height of the ridge element 2a has the maximum value hmax at the position of the vertex position x2. However, the ridge element 2a may be such that a section where the height is substantially the same as the maximum height hmax continues rearward from the vertex position x2 and the height gradually drops from the section to the rear end position x3.
A ridgeline connecting vertexes of the transverse sectional shapes of the ridge structure 2 at each chord position x (x1<x<x3) forms an angle of a ridgeline angle θR relative to the chord direction. However, the ridgeline angle θR is changed suitably depending on the position (x, z) on the top face 1c of the wing 1, and the ridgeline is curved. The ridgeline angle θR is an angle between a boundary layer edge velocity yaw angle θe of a flow line on the boundary layer external edge and a cross-flow instability angle θcf on a wavefront of a stationary cross-flow instability. It is desirable that the ridgeline angle θR be around an intermediate value (=(θe+θcf)/2). For the ridgeline angle θR, however, a slight error around 30% or less of the angle difference (θe−θcf) relative to the intermediate value is tolerable.

Parameters characterizing the wave-shaped ridge structure 2 described above are the wavenumber βR, the front end position x1, the vertex position x2, the rear end position x3, the maximum height hmax, and the ridgeline angle θR. With selection of the optimal values thereof, a significant reduction effect on the frictional resistance is obtained. However, parameters more deviate from the optimal values will weaken the effect and may even result in an adverse effect. Thus, in design, it is required to select the parameters of the ridge structure 2 optimally in accordance with the strength of a flow field or airflow turbulence.

Next, information on the flow field required for design of the wave-shaped ridge structure 2 will be described.

Since the flow around a columnar object is accelerated in the chord direction from a position of a stagnation point, a flow line on the boundary layer external edge when a swept-back angle exists is curved as illustrated in FIG. 1. Furthermore, it is known that a cross-flow occurs in a direction perpendicular to this flow line inside the boundary layer.

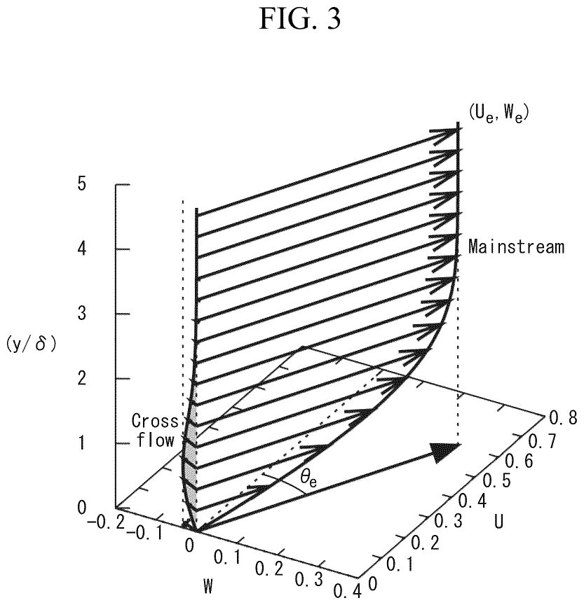

FIG. 3 illustrates a typical flow velocity distribution at a certain position on an object surface. Such a specific flow velocity distribution of the boundary layer developing around an object can be found by a fluid simulation or alternatively may be measured experimentally if a hot wire anemometer is used.

It is here assumed that the flow velocity distribution of a boundary layer at a position (x, z) on the top face 1c of the wing 1 is (U(y), W(y)). Herein, U(y) represents a flow velocity component in the chord direction, and W(y) represents a flow velocity component in the span direction. When the 99% boundary layer thickness of a boundary layer is denoted as δ99, the flow velocity (U(y), W(y))=(U(δ99), W(δ99)) at that thickness can be approximately considered as the velocity on the boundary layer external edge. The angle θe=arctan(We/Ue) is an angle formed between the chord direction and the external edge flow velocity direction at this position.

In the leading edge region of the wing 1, the object shape and the flow field do not substantially change in the span direction (z direction) compared to the chord direction (x direction) and can thus be considered as substantially even in the span direction as with a columnar object. The stationary cross-flow instability is a mode in which a standing wave having a substantially periodical wavenumber R in the span direction exponentially amplifies while propagating in the chord direction and appears as a stationary vortex row. A spatial growth rate of stationary cross-flow instability at each position on the object surface can be found by numerically performing linear stability analysis of the flow velocity distribution (U(y), W(y)) of the boundary layer.

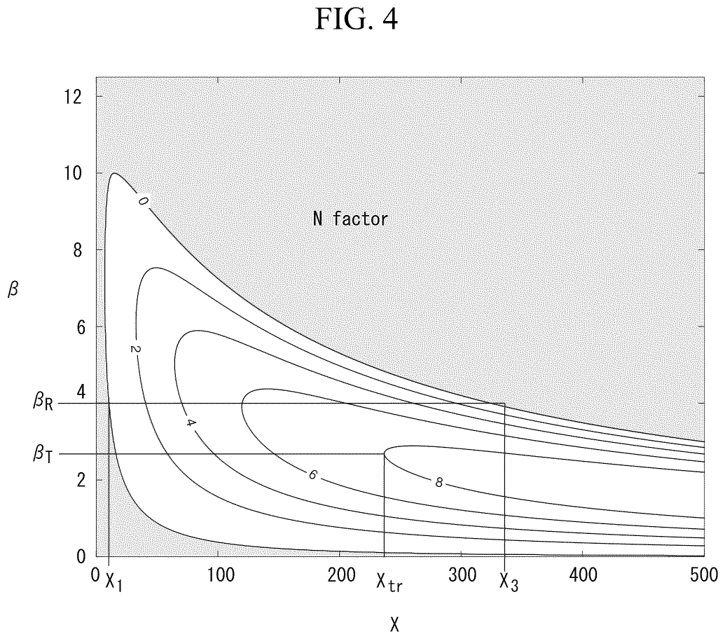

An approximate occurrence position of a boundary-layer transition is predicted by the N-factor that is an integral of the spatial growth rate in the chord direction. FIG. 4 is an example of the N-factor of stationary cross-flow instability obtained by linear stability analysis. In such a way, it is known that the N-factor differs in accordance with the wavenumber β. For example, in a case of an airplane in a cruising state, it is said that a boundary-layer transition takes place when the N-factor reaches 8 to 10 (the disturbance amplitude amplifies from about e⁸ times to e¹⁰ times). Note that the larger the airflow turbulence is, the lower the threshold thereof tends to be.

For example, when it is assumed that a transition occurs at N=8, a position xtr at which the transition occurs and the wavenumber DT of the disturbance that causes the transition are predicted as illustrated in FIG. 4. That is, since the target is to suppress the cross-flow instability having this wavenumber, OT is here referred to as a target wavenumber.

Further, it is theoretically known that the cross-flow instability angle θcf of a wavefront of stationary cross-flow instability relative to the chord direction has a value defined for each place. Specifically, when the following flow velocity component is defined:

U_{ζ}(y)=−U(y)sin θcf+W(y)cos θcf,

an angle at which an inflection point of U_{ζ}(y) just matches the zero point can be found as the cross-flow instability angle θcf. Herein, θcf is an angle slightly smaller than Be.

The above quantities can be defined for each position (x, z) on an object surface and are thus given as a function of (x, z).

Next, a method of determining the optimal parameters will be described.

First, the wavenumber DR in the span direction of the wave-shaped ridge structure 2 is assumed to be a wavenumber around 3/2 times of the target wavenumber βT. This wavenumber OR is unstable against cross-flow instability but corresponds to a disturbance whose growth rate and N-factor are smaller than those of the target wavenumber βT.

The position around which a disturbance of the wavenumber βR starts growing is defined as the front end position x1 that is a start position of the ridge structure 2.

The maximum height hmax of the ridge element 2a is approximately the same as the 99% boundary layer thickness δ99 at the front end position x1. While an increase of the maximum height hmax enhances the effect, an excessively increased height will cause the ridge structure 2 to be a turbulent flow source. Thus, a limit height exists in accordance with the strength of airflow turbulence. For example, in an environment of strong airflow turbulence, it is preferable to suppress the maximum height hmax to about 0.6 times, preferably, about 0.8 times of δ99. In contrast, in a case of an airflow with small turbulence such as a flight environment, the suppression effect may be exerted even when the maximum height hmax is increased to 1.5 times, preferably, 1.4 times of δ99.

For the vertex position x2, it is preferable to set the section width x2−x1 to about three to four times of the maximum height hmax so that the section where the height of the ridge structure 2 increases to the maximum height hmax from zero is not of a steep gradient.

Although the rear end position x3 of the ridge structure 2 is a rearward position beyond at least a region where the wavenumber 3R is unstable, the rear end position x3 may be located more rearward than the rearward position. If the ridge structure 2 is expanded rearward, the boundary-layer transition position also recedes rearward, and the turbulent flow suppression effect will increase. However, since the increase in the turbulent flow suppression effect gradually becomes smaller, the benefit to be obtained by the rearward expansion of the ridge structure 2 becomes smaller.

The ridgeline angle θR that is an angle of the ridgeline of the ridge structure 2 relative to the chord direction is assumed to be between the boundary layer edge velocity yaw angle θe and the stationary cross-flow instability angle θcf. Preferably, it is optimal to perform machining so that the ridgeline angle θR is the intermediate value, that is:

θR=(θe+θcf)/2.

If θR is closer to the θe side, the turbulent flow suppression effect will be weaker, and if θR is closer to the θcf side, a turbulent flow will be more likely to occur from the ridge structure 2. Both θe and θcf vary in accordance with a position on the surface of the wing 1, and θcf is a value always smaller than θe. That is, OR also varies in accordance with a position, and the ridgeline of the ridge structure 2 that is an integral thereof is a curve that is moderately curved.

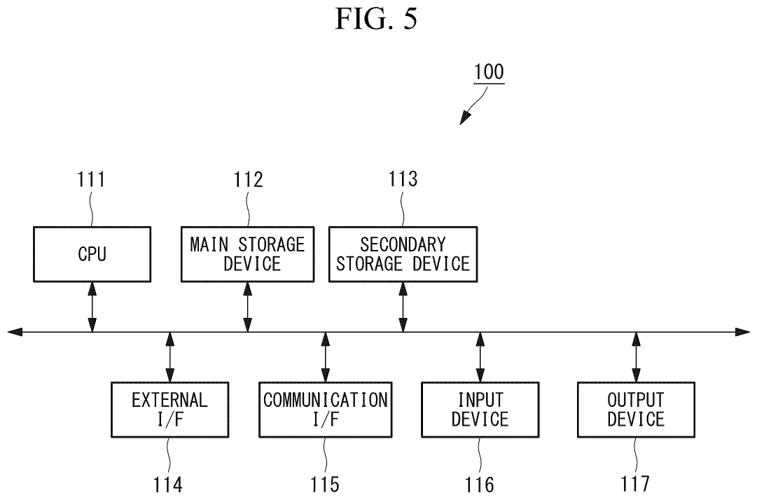

As illustrated in FIG. 5, a computer 100 that executes a design program that implements a design method for designing the ridge structure described above has a central processing unit (CPU: processor) 111, a main storage device (main memory) 112, a secondary storage device (secondary storage: memory) 113, and the like, for example.

The CPU 111 controls the overall computer 100 by using operating system (OS) stored in the secondary storage device 113 connected via a bus and performs various processes by executing various programs stored in the secondary storage device 113, for example. One or a plurality of CPUs 111 are provided and may implement the process in cooperation with each other. Further, the computer 100 has an input device 116 and an output device 117. An example of the input device may be a keyboard, a touch pad, a pointing device, or the like. An example of the output device may be a display, a projector, a printer, or the like.

The main storage device 112 is formed of a rewritable memory such as a cache memory, a random access memory (RAM), or the like, for example, and used as a work area where an execution program of the CPU 111 is read or loaded, processing data caused by an execution program is written, or the like.

The secondary storage device 113 is a non-transitory computer readable storage medium. The secondary storage device 113 may be, for example, a magnetic disk, a magneto-optical disk, a CD-ROM, a DVD-ROM, a semiconductor memory, or the like. An example of the secondary storage device 113 may be a read only memory (ROM), a hard disk drive (HDD), a solid state drive (SSD) flash memory, or the like. For example, the secondary storage device 113 stores OS used for controlling the overall information processing device, such as Windows (registered trademark), iOS (registered trademark), Android (registered trademark), or the like, Basic Input/Output System (BIOS), various device driver used for operating peripherals as hardware, various application software, and various data and files or the like. Further, the secondary storage device 113 stores programs used for implementing various processes and various data required for implementing various processes. A plurality of secondary storage devices 113 may be provided, and the program or the data as described above may be divided and stored in each of the secondary storage devices 113.

A series of processes for implementing the function of the computer 100 is stored in the secondary storage device 113 or the like in a form of a program, and various functions are implemented when the CPU (processor) 111 loads the program into the main storage device 112 and performs processing and computation of information. Note that the program may be a program to which a form of being preinstalled in the secondary storage device 113, a form of being provided in a state of being stored in another non-transitory computer readable storage medium, a form of being delivered via a wired or wireless communication unit, or the like may be applied. An example of the non-transitory computer readable storage medium may be a magnetic disk, a magneto-optical disk, a CD-ROM, a DVD-ROM, a semiconductor memory, or the like.

Next, the mechanism when the ridge structure 2 described above is employed will be described.

Micro-roughness on the surface of an object, dirt attached to the surface, or the like act as a stationary disturbance source and disturb a flow, and stationary cross-flow instability is excited. At this time, a wave of the target wavenumber OT having the largest amplification factor becomes notable and appears as a vortex row. This vortex row further secondarily becomes unstable and thereby finally transitions to a turbulent flow.

The instability of the wavenumber βR that is a higher wavenumber than the target wavenumber βT not only has a smaller amplification factor but also tends to be less likely to cause a boundary-layer transition. Thus, by artificially, strongly exciting the stationary cross-flow instability of the wavenumber βR, it is possible to suppress growth of instability of the wavenumber OT without causing a boundary-layer transition.

To increase this suppression effect, it is desirable to maintain a vortex row, which is generated by the stationary cross-flow instability of the wavenumber βR, over a wide region at a moderate strength. In this region, the growth of the instability of the wavenumber OT is suppressed, and the position at which a boundary-layer transition takes place moves downstream for the suppression.

The wave-shaped ridge structure 2 of the present embodiment has the structure optimized for selectively exciting such a vortex row of the wavenumber OR and stationarily maintaining the excited vortex row without collapsing the same.

Once the position at which a boundary-layer transition takes place recedes downstream, the region of the laminar flow boundary layer expands for the recession, and the frictional resistance applied to the object is reduced. This is an eventual advantageous effect obtained by the present embodiment.

Cross-flow instability occurs only in a region where a favorable pressure gradient on an object surface is present (a region where a flow is accelerated), which is often concentrated near the leading edge in a case of a wing section object. If a boundary-layer transition due to cross-flow instability can be completely suppressed in this region, it is possible to cause the boundary-layer transition position to significantly recede.

### EXAMPLE

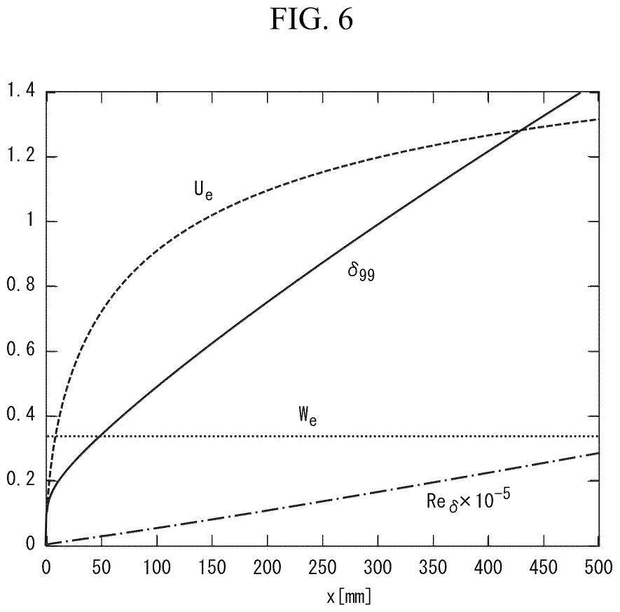

In a case of Falkner-Skan-Cooke solution that is a representative three-dimensional boundary layer that develops on a flat plate, the effect of the present embodiment is illustrated through a direct numerical simulation. An assumed flow velocity corresponds to a transonic flow that is similar to the environment around a swept-back wing of an aircraft, and specifically, a case of the external edge velocity distribution illustrated in FIG. 6 is considered. Herein, the flow velocity is normalized by a sound velocity of 311 m/s on the leading edge, and the length is normalized by 1 mm. As illustrated in FIG. 6, the thickness 899 of the boundary layer depends on the distance from leading edge x=0 and is in the order of several hundred sm. The flow is completely even in the span direction. In FIG. 6, Re_{δ} denotes a local Raynolds number, which is expressed as Re_{δ}=(Ue²+We²)^{1/2}*δ99/v₀. Herein, v₀ is a coefficient of kinematic viscosity at the leading edge position x=y=0.

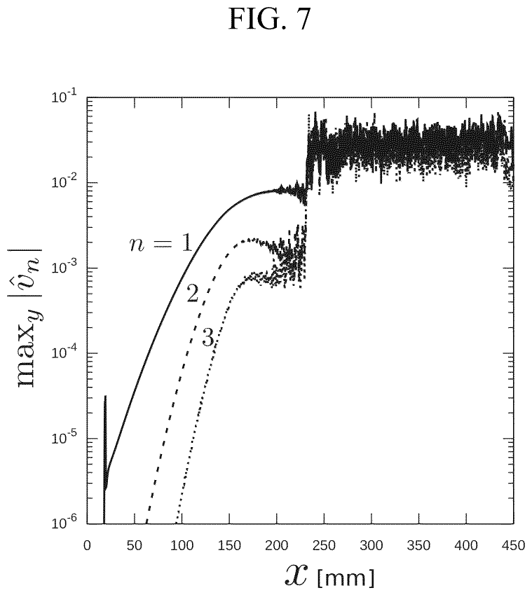

The target wavenumber γT is 3.333 mm⁻¹, and FIG. 7 illustrates a view in which the amplitude of the Fourier component of this wavenumber unstably amplifies and causes a boundary-layer transition. The value max_{y}|v\hat{ }n| (note that “v\hat{ }” is a symbol in which \hat{ } (hat) is located above v (the same applies hereafter)) of the vertical axis of the graph is a value obtained by performing discrete Fourier transform on the wall normal direction velocity (v) in the span direction and taking the maximum value of the amplitude |v\hat{ }n| with respect to the wall normal direction (y direction). Each Fourier component is labeled with an integer such as n=1, 2, . . . , and corresponds to the component of the span direction wavenumber γ=3.333n mm⁻¹. In this numerical simulation, a disturbance source of the wavenumber βT is given to the position of x=20, and this sharply transitions to a turbulent flow from around x=230, which also depends on the strength of the given disturbance. In the following, the target mode is to be suppressed, and control to move the transition position rearward is performed.

First, as a comparative example, the SRE disclosed in Patent Literature 1 will be considered.

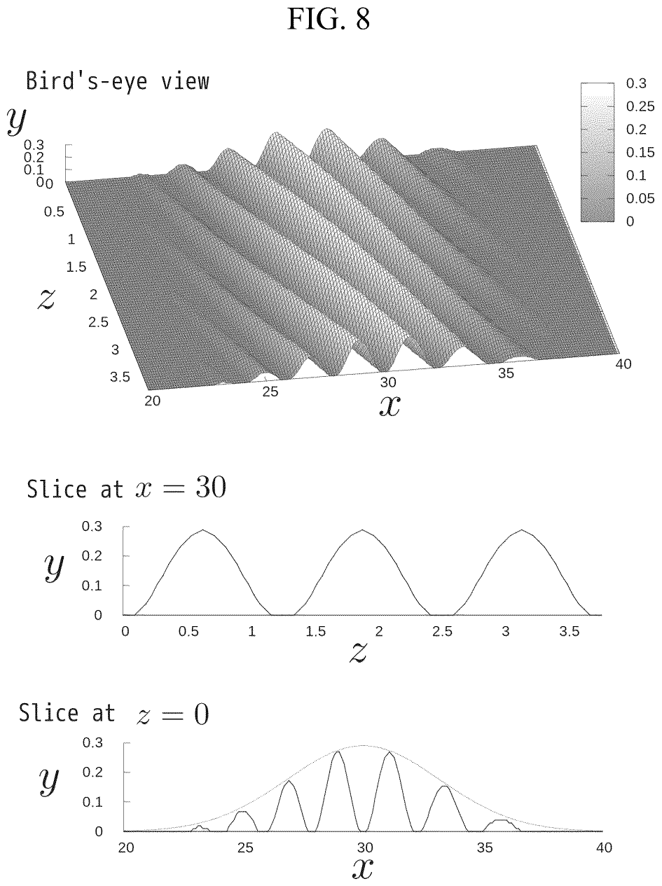

In the following, shapes are defined by a function yR(x, z) representing a height distribution of a ridge structure. The shape example of the SRE of Patent Literature 1 is as follows:

$${y}_{R} ( x , z ) = h \frac{1 - sin {β}_{R} [ z - {z}_{e} ( x ) ]}{2} f ( x ) , \qquad [ Math . 1 ]$$

$${z}_{e} ( x ) = \frac{{W}_{e} ( {x}_{2} )}{{U}_{e} ( {x}_{2} )} ( x - {x}_{2} ) ,$$

$$f ( x ) = exp [ - π \frac{{( x - {x}_{2} )}^{2}}{{8}^{2}} ]$$

where βR=5 mm⁻¹ (2π/βR=1.26 mm), x2=30 mm, and h=0.3 mm are selected as parameters. The function z=ze(x) represents a line oriented to the flow line direction at a position of x=x2, and this corresponds to a ridgeline of a single ridge portion. FIG. 8 illustrates a view rendering such a shape.

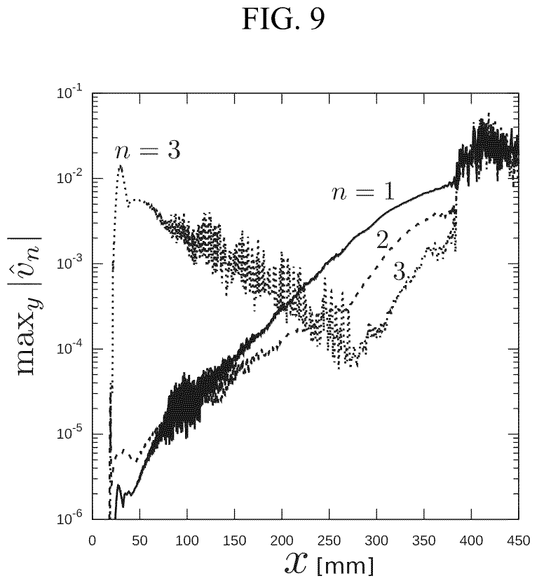

FIG. 9 illustrates a result when this SRE is installed in a wing. The component of the wavenumber βR is strongly excited at the position x2=30 mm of the SRE and attenuated as it approaches the rear side. This corresponds to that a vortex row of this wavenumber is excited and then attenuated. It can be seen that amplification of the target wavenumber βT=3.333 (n=2) and the wavenumber of 1.666 (n=1) is suppressed and the position of the boundary-layer transition recedes to around x=380 mm. The heigh h=0.3 mm of the SRE is substantially the limit, and a height higher than this limit will cause a turbulent flow to occur from a protrusion of the SRE and result in an adverse effect.

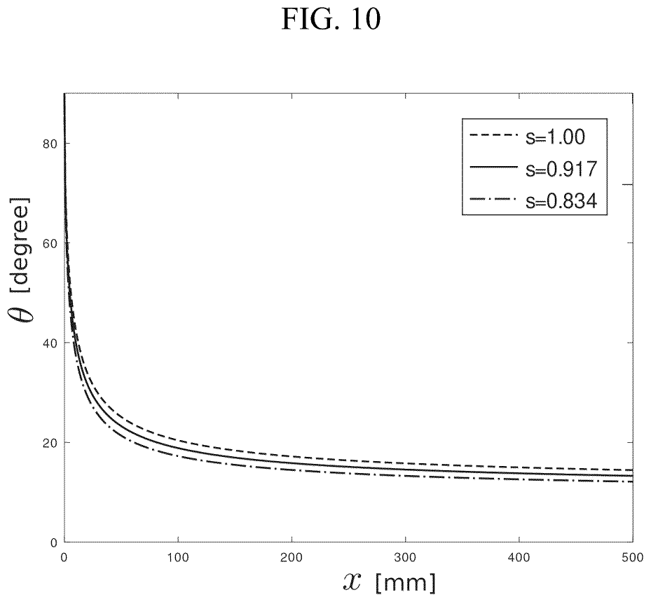

As the present Example, the following shape is considered.

$${y}_{R} ( x , z ) = h \frac{1 - sin {β}_{R} [ z - {sz}_{e} ( x ) ]}{2} f ( x ) , \qquad [ Math . 2 ]$$

$${z}_{e} ( x ) = {\int }_{{x}_{2}}^{x} \frac{{W}_{e} ( x )}{{U}_{e} ( x )} dx$$

$$f ( x ) = \{ \begin{matrix}exp [ - π \frac{{( x - {x}_{R} )}^{2}}{{8}^{2}} ] & x < {x}_{2} \\ 1 - {( x - {x}_{R} )}^{2} / {400}^{2} & x > {x}_{2}\end{matrix}$$

where parameters are set as βR=5 mm⁻¹ (2π/βR=1.26 mm) and xR=30 mm, and this setting is the same as that in the SRE described above. A significant difference from this SRE is that f(x) is widely distributed up to a position of x=400 mm and the ridge structure 2 expands up to the leading edge region rearward of the leading edge portion instead of up to a local region near the leading edge portion. Further, the function z=ze(x) represents a flow line that is an integral in the flow line direction. If the parameter s is set as s=1 in the above shape, the ridgeline of the convex part is curved so as to match the flow line outside the boundary layer. On the other hand, in the boundary layer considered herein, if s=0.834, the ridgeline matches a wavefront of stationary cross-flow instability. FIG. 10 illustrates the boundary layer edge velocity yaw angle θe at each chord position x and the cross-flow instability angle θcf representing the wavefront direction of stationary cross-flow instability. Thus, the optimal angle proposed in the present Example corresponds to selection of s=0.917, and a significant suppression effect on the turbulent flow is obtained by extending the ridgeline along the ridgeline angle θR representing such a direction.

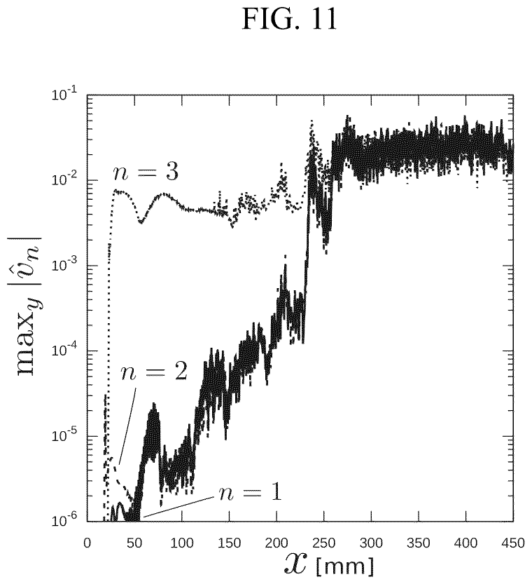

FIG. 11 to FIG. 13 illustrate results of numerical simulations when s=0.834, 0.917, and 1 are actually applied. Note that the limit of the height h differs for each case.

FIG. 11 illustrates, as a comparative example, the result of the numerical simulation in the case of s=0.834, that is, the ridgeline of the ridge element matches the wavefront of stationary cross-flow instability. In this case, the height is set to h=0.23. As can be seen from data at n=3, despite the low height of h=0.23, the vortex row generated by the ridge structure is collapsed, and a boundary-layer transition occurs.

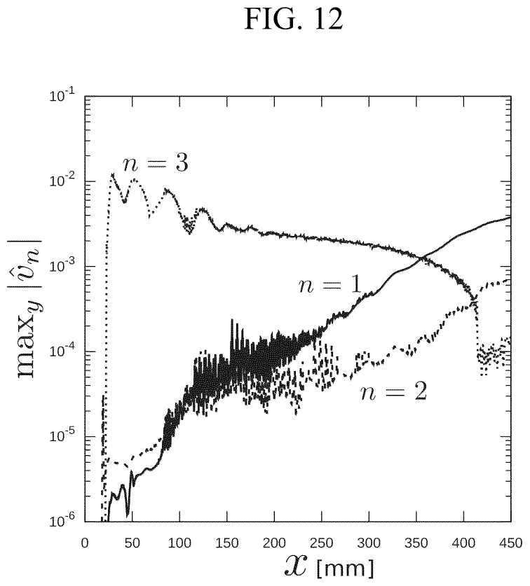

FIG. 12 illustrates, as a comparative example, the result of the numerical simulation in the case of s=1, that is, the ridgeline of the ridge element matches a flow line outside the boundary layer. In this case, the height is set to h=0.27. As can be seen from FIG. 12, no boundary-layer transition is caused, and a larger suppression effect is obtained than the SRE described above (see FIG. 9). The boundary-layer transition does not actually occur in the calculation region and recedes to a more rear position. However, the Fourier component (n=3) of the wavenumber OR significantly oscillates in the range of 30 mm<x<150 mm. This is because there is a mismatch between the concave and convex pattern of the ridge structure and the angle of the stationary vortex row, both the patterns thereof interfere with each other, and the vortex row undulates so as to ride over the concave and convex pattern. Thus, if the height is higher than h=0.27, the vortex row will collapse, and therefore, this height is the limit.

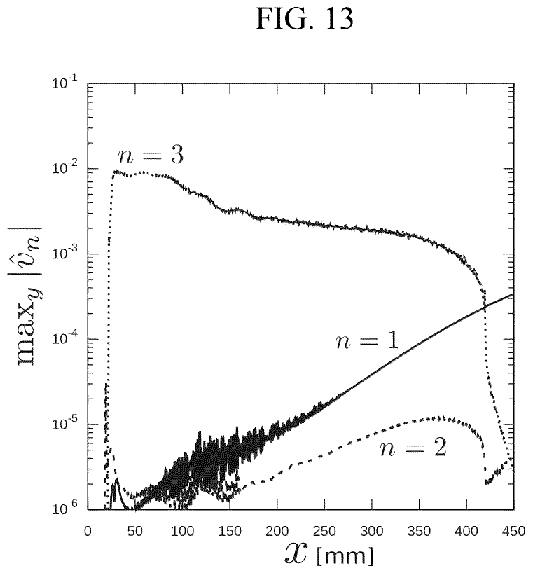

FIG. 13 illustrates, as the present Example, the result of the numerical simulation in the case of s=0.917. In this case, the height is set to h=0.4. As can be seen from FIG. 13, the Fourier component (n=3) of the wavenumber OR does not oscillate, maintains a large amplitude up to x=400 mm in the same manner as the concave and convex pattern of the ridge structure, and is gradually attenuated. The concave and convex pattern of the ridge structure and the stationary vortex row have substantially the same phase, and even when the height is increased to h=0.4, no turbulent flow occurs. The amplitude of a disturbance intended to be suppressed is reduced by one order or greater of magnitude compared to the case of s=1, which indicates that the boundary-layer transition position is also significantly moved rearward accordingly.

The effects and advantages of the present embodiment described above are as follows.

The ridgeline angle θR is set between the boundary layer edge velocity yaw angle θe and the cross-flow instability angle θcf, and thereby a vortex row formed by the ridge structure 2 can be stationarily maintained along the ridgeline angle θR. Accordingly, it is possible to cause a boundary-layer transition to recede and thereby reduce the frictional resistance.

The ridge structure, the wing, the design method of the ridge structure, and the design program for the same of each embodiment described above are understood as follows, for example.

The ridge structure (2) according to a first aspect of the present disclosure has a plurality of ridge elements (2a) provided on a surface of a leading edge region directly downstream of a leading edge (1a) and extending in parallel toward downstream of a mainstream, the leading edge region is a laminar flow region of an object having a swept-back angle relative to the mainstream and provided with the leading edge, and the plurality of ridge elements have vertexes provided at a constant interval λR in a z direction parallel to a leading edge attachment line (L1) on which stagnation points attached to the leading edge are aligned. When an angle of a ridgeline connecting the vertexes of the ridge elements in an extending direction of the ridge elements relative to an x direction perpendicular to the leading edge attachment line is defined as a ridgeline angle θR, an angle of a flow line of a boundary layer external edge of the mainstream relative to the x direction is defined as a boundary layer edge velocity yaw angle θe, and an angle of a wavefront of stationary cross-flow instability, which is a mode in which a stationary disturbance amplifies inside a boundary layer of the surface and appears as a stationary vortex row, relative to the x direction is defined as a cross-flow instability angle θcf, the ridgeline angle θR is set between the boundary layer edge velocity yaw angle θe and the cross-flow instability angle θcf.

As a result of an intensive study by the present inventors, it has been found that, when the ridgeline angle θR is set between the boundary layer edge velocity yaw angle θe and the cross-flow instability angle θcf, a vortex row formed by the ridge structure can be stationarily maintained along the ridgeline angle θR. The ridgeline angle θR is preferably the intermediate value between the boundary layer edge velocity yaw angle Ae and the cross-flow instability angle θcf(=(θe+θcf)/2), and a slight error around 30% or less of the angle difference (θe−θcf) relative to the intermediate value is tolerable. Note that, if OR is closer to the θe side, the turbulent flow suppression effect will be weaker, and if OR is closer to the θcf side, a turbulent flow will be more likely to occur from the ridge structure.

With respect to the cross-flow instability angle θcf, when the following flow velocity component is defined:

U_{ζ}(y)=−U(y)sin θcf+W(y)cos θcf,

an angle at which an inflection point of U_{ζ}(y) matches the zero point can be found as the cross-flow instability angle θcf. The cross-flow instability angle θcf is an angle smaller than the boundary layer edge velocity yaw angle θe. Herein, y denotes a position in an object surface normal direction (y=0 corresponds to the object surface) inside the boundary layer, z denotes a position in a direction parallel to the leading edge attachment line (the span direction), U(y) denotes a flow velocity component in the x direction at y, and W(y) denotes a flow velocity component in the z direction at y.

In the ridge structure according to the second aspect of the present disclosure, in the above first aspect, a wavenumber βR corresponding to the interval λR of the vertexes of the ridge elements is:

1.3βT≤βR≤1.7βT,

where a wavenumber set based on a boundary-layer transition obtained from a spatial growth rate of stationary cross-flow instability is a target wavenumber βT.

The wavenumber BR corresponding to the interval λR of vertexes of the ridge elements (=2π/λR) is set in accordance with the wavenumber βT set based on a boundary-layer transition obtained from a spatial growth rate of stationary cross-flow instability. The wavenumber βT can be obtained from the N-factor distribution that is an integral of the spatial growth rate in the x direction.

The spatial growth rate of stationary cross-flow instability at each position on an object surface can be found by numerically performing linear stability analysis on the flow velocity distribution (U(y), W(y)) of the boundary layer. The N-factor can be represented as contour lines on the xy-plane on which x-axis represents the x direction and y-axis represents the wavenumber β.

The ridge element shape appearing periodically at the interval λR is a sine wave, a triangular wave, or the like, for example.

In the ridge structure according to the third aspect of the present disclosure, in the above second aspect, a front end position x1 in the x direction of the ridge elements is a position at which a disturbance of the wavenumber βR starts growing.

The front end position x1 of the ridge elements is provided at a position at which a disturbance of the wavenumber βR starts growing, and thereby the growth of the generated disturbance of the wavenumber βR can be maintained. The front end position x1 can be obtained from the diagram illustrating the contour lines of the N-factor described above.

In the ridge structure according to the fourth aspect of the present disclosure, in the above second aspect or the above third aspect, a rear end position x3 in the x direction of the ridge elements is provided at a position at which a disturbance of the wavenumber OR stops growing or provided on a tailing edge side from the position.

The rear end position x3 of the ridge elements is provided at a position at which a disturbance of the wavenumber OR stops growing or provided on a tailing edge side from the position, and thereby the growth of a disturbance of the wavenumber OR can be maintained. The position at which the growth of a disturbance of the wavenumber OR ends can be obtained from the diagram illustrating the contour lines of the N-factor described above.

In the ridge structure according to the fifth aspect of the present disclosure, in the above second aspect or the above fourth aspect, the maximum height hmax from the surface of the leading edge region of the ridge elements is greater than or equal to 0.6 times and less than or equal to 1.5 times of a 99% boundary layer thickness δ99 at the front end position x1.

When the maximum height hmax is less than 0.6 times of δ99, no growth of a disturbance of the wavenumber βR may be expected. When the maximum height hmax is greater than 1.5 times of δ99, the ridge structure may become a turbulent flow source.

In the ridge structure according to the sixth aspect of the present disclosure, in any one of the above third aspect to the above fifth aspect, a distance from the front end position x1 to a vertex position x2 at the maximum height hmax is greater than or equal to three times and less than or equal to four times of the maximum height hmax.

It is preferable to set x2−x1 to be greater than or equal to three times and less than or equal to four times of the maximum height hmax so that the section from the front end position x1 to the vertex position x2 is not of a steep gradient. It is preferable that the maximum height hmax be maintained to rearward of the vertex position x2, and in such a case, the height gradually decreases from a position in front of the rear end position x3 over a distance of 30% or longer of x3−x2.

The wing according to one aspect of the present disclosure has the ridge structure of any one of the above first aspect to the above sixth aspect.

Since the ridge structure described above is provided, a wing with a reduced frictional resistance is realized.

The design method of a ridge structure according to one aspect of the present disclosure is a designing method of a ridge structure, the ridge structure has a plurality of ridge elements provided on a surface of a leading edge region directly downstream of a leading edge and extending in parallel toward downstream of a mainstream, the leading edge region is a laminar flow region of an object having a swept-back angle relative to the mainstream and provided with the leading edge, and the plurality of ridge elements have vertexes provided at a constant interval λR in a z direction parallel to a leading edge attachment line on which stagnation points attached to the leading edge are aligned. The design method includes: when an angle of a ridgeline connecting the vertexes of the ridge elements in an extending direction of the ridge elements relative to an x direction perpendicular to the leading edge attachment line is defined as a ridgeline angle θR, an angle of a flow line of a boundary layer external edge of the mainstream relative to the x direction is defined as a boundary layer edge velocity yaw angle θe, and an angle of a wavefront of stationary cross-flow instability that is a mode in which a stationary disturbance amplifies inside a boundary layer of the surface and appears as a stationary vortex row, relative to the x direction is defined as a cross-flow instability angle θcf, setting the ridgeline angle θR between the boundary layer edge velocity yaw angle Ae and the cross-flow instability angle θcf.

The design program according to one aspect of the present disclosure causes a computer to perform the design method described above.

### REFERENCE SIGNS LIST

1 wing (object)
1a leading edge
1b tailing edge
1c top face
2 ridge structure
F (mainstream) flow
L1 leading edge attachment line
x1 front end position
x2 vertex position
x3 rear end position
OR ridgeline angle
θcf cross-flow instability angle
θe boundary layer edge velocity yaw angle
θ∞ swept-back angle
λR (ridge element) interval

1. A ridge structure comprising a plurality of ridge elements provided on a surface of a leading edge region directly downstream of a leading edge and extending in parallel toward downstream of a mainstream, the leading edge region being a laminar flow region of an object having a swept-back angle relative to the mainstream and provided with the leading edge,
wherein the plurality of ridge elements have vertexes provided at a constant interval λR in a z direction parallel to a leading edge attachment line on which stagnation points attached to the leading edge are aligned, and
wherein when
an angle of a ridgeline connecting the vertexes of the ridge elements in an extending direction of the ridge elements relative to an x direction perpendicular to the leading edge attachment line is defined as a ridgeline angle θR,
an angle of a flow line of a boundary layer external edge of the mainstream relative to the x direction is defined as a boundary layer edge velocity yaw angle θe, and
an angle of a wavefront of stationary cross-flow instability, which is a mode in which a stationary disturbance amplifies inside a boundary layer of the surface and appears as a stationary vortex row, relative to the x direction is defined as a cross-flow instability angle θcf,
the ridgeline angle θR is between the boundary layer edge velocity yaw angle θe and the cross-flow instability angle θcf.

2. The ridge structure according to claim 1, wherein a wavenumber βR corresponding to the interval λR of the vertexes of the ridge elements is: where a wavenumber set based on a boundary-layer transition obtained from a spatial growth rate of stationary cross-flow instability is a target wavenumber βT.

3. The ridge structure according to claim 2, wherein a front end position x1 in the x direction of the ridge elements is a position at which a disturbance of the wavenumber OR starts growing.

4. The ridge structure according to claim 3, wherein a rear end position x3 in the x direction of the ridge elements is provided at a position at which a disturbance of the wavenumber OR stops growing or provided on a tailing edge side from the position.

5. The ridge structure according to claim 3, wherein the maximum height hmax from the surface of the leading edge region of the ridge elements is greater than or equal to 0.6 times and less than or equal to 1.5 times of a 99% boundary layer thickness δ99 at the front end position x1.

6. The ridge structure according to claim 5, wherein a distance from the front end position x1 to a vertex position x2 at the maximum height hmax is greater than or equal to three times and less than or equal to four times of the maximum height hmax.

7. A wing comprising the ridge structure according to claim 1.

8. A design method of a ridge structure, wherein the ridge structure comprises a plurality of ridge elements provided on a surface of a leading edge region directly downstream of a leading edge and extending in parallel toward downstream of a mainstream, the leading edge region being a laminar flow region of an object having a swept-back angle relative to the mainstream and provided with the leading edge,
wherein the plurality of ridge elements have vertexes provided at a constant interval λR in a z direction parallel to a leading edge attachment line on which stagnation points attached to the leading edge are aligned,
the design method comprising: when
an angle of a ridgeline connecting the vertexes of the ridge elements in an extending direction of the ridge elements relative to an x direction perpendicular to the leading edge attachment line is defined as a ridgeline angle θR,
an angle of a flow line of a boundary layer external edge of the mainstream relative to the x direction is defined as a boundary layer edge velocity yaw angle θe, and
an angle of a wavefront of stationary cross-flow instability, which is a mode in which a stationary disturbance amplifies inside a boundary layer of the surface and appears as a stationary vortex row, relative to the x direction is defined as a cross-flow instability angle θcf,
setting the ridgeline angle θR between the boundary layer edge velocity yaw angle θe and the cross-flow instability angle θcf.

9. A non-transitory tangible computer-readable storage medium storing a design program for a ridge structure, the design program causing a computer to perform the design method according to claim 8.
